(19) United States
(12) Patent Application Publication
(10) Pub. No.: US 2012/0038065 A1
(43) Pub. Date: Feb. 16, 2012

(54) Method for Producing an Electrical Circuit and Electrical Circuit

(75) Inventors: Juergen Butz, Reutlingen (DE); Axel Franke, Ditzingen (DE); Frieder Haag, Wannweil (DE); Heribert Weber, Nuertingen (DE); Arnim Hoechst, Reutlingen (DE); Sonja Knies, Rutesheim (DE)

(73) Assignee: Robert Bosch GmbH, Stuttgart (DE)

(21) Appl. No.: 13/206,271

(22) Filed: Aug. 9, 2011

(30) Foreign Application Priority Data
Aug. 10, 2010 (DE) 10 2010 039 156.5

(51) Int. Cl. H01L 21/56; H01L 23/498

(52) U.S. Cl. 257/784; 438/127; 257/E23.06; 257/E21.502

(57) ABSTRACT

A method for producing an electrical circuit having at least one semiconductor chip is disclosed. The method includes forming a wiring layer at a contact side of the at least one semiconductor chip, which is encapsulated with a potting compound apart from the contact side. The wiring layer has at least one conductor loop for the purpose of forming an electrical coil.

This application claims priority under 35 U.S.C. §119 to German patent application no. DE 10 2010 039 156.5, filed Aug. 10, 2010 in Germany, the disclosure of which is incorporated herein by reference in its entirety.

### BACKGROUND

The present disclosure relates to a method for producing an electrical circuit comprising at least one semiconductor chip, to an electrical circuit comprising at least one semiconductor chip, and to a sensor module comprising the electrical circuit.

So-called wafer level packaging is used in chip construction and connection technology. In this case, the individual packaging processes are carried out on the silicon wafer or on an arrangement in the wafer format.

U.S. Pat. No. 3,579,056 A1 describes a method for producing a semiconductor device, wherein semiconductor components are fitted onto a carrier and are enclosed by a polyurethane layer. Afterward, the carrier is removed, and conductors for the semiconductor components are fitted.

### SUMMARY

Against this background, the present disclosure presents a method for producing an electrical circuit comprising at least one semiconductor chip and an electrical circuit comprising at least one semiconductor chip possessing the features set forth herein. Advantageous configurations are evident from the following description.

The disclosure is based on the insight that producing a chip package in the wafer level process with integration of a coil affords considerable advantages. For a wafer level package with an integrated coil, a known approach of wafer level packaging can be extended and the additional function of a coil can be integrated into the package.

In the wafer level process, chips are placed on a temporary carrier substrate. Afterward, by means of a molding compound, a chip-molding compound wafer is produced, on which a new wiring plane for electrical contact-connection is produced after removal of the carrier substrate. The task of the wiring plane is to spread the connection grid from very fine, as on the original silicon wafer, to coarser dimensions for linking to a printed circuit board, which cannot realize the fine structures on account of the production technology.

The advantages of the disclosure are that the production process for the coil can be integrated directly into the wafer level package process sequence. Moreover, as necessary, the package size, in particular the lateral dimensions, can be extended cost-effectively if the existing silicon chip area is not sufficient for the coil. Advantageously, energy can be coupled into the system through the coil via radio, such that said system can be addressed and read by radio.

The present disclosure provides a method for producing an electrical circuit comprising at least one semiconductor chip, comprising the following step:

forming a wiring layer at a contact side of the at least one semiconductor chip, which is encapsulated with a potting compound apart from the contact side, wherein the wiring layer has at least one conductor loop for the purpose of forming an electrical coil.

An electrical circuit can be understood to be an integrated circuit having a plurality of electronic components. The electrical circuit can be provided in the form of a wafer level package. The semiconductor chip can be a semiconductor component, for example a silicon chip. In this case, the circuit can have one or a plurality of semiconductor chips. The semiconductor chip can be present in packaged or housed fashion and can be provided with contact connections. The circuit can have a layer construction, wherein the wiring layer can be understood to be a wiring plane in the layer construction of the circuit. The wiring layer serves principally for providing contact lines for making contact with the semiconductor chip and for providing circuit-internal electrical connections between the electronic components of the circuit. The wiring layer is formed by a semiconductor technology method, such as e.g. metal sputtering, resist coating, lithography or electrodeposition. The wiring layer can extend beyond an area of the contact side of the semiconductor chip. The contact side of the semiconductor chip is the active side thereof, at which electrical contacts of the chip are also situated. The semiconductor chip is encapsulated in the potting compound, wherein the contact side is not covered with potting compound, such that the wiring layer or an intervening wiring layer can be formed directly on a surface of the contact side. In this case, a potting compound can be understood to be a molding material, a molding compound, also known as mold compound. The at least one semiconductor chip with the potting compound can be present in the configuration of a type of molding compound composite wafer. This affords the advantage that it is thus possible to provide an efficiently processable assembly to which the wiring layer can be applied. A conductor loop can be understood to be a conductor track or electrical line which is arranged for the purpose of forming the electrical coil in the form of at least one winding in the wiring layer. A conductor forming the at least one conductor loop can be formed simultaneously with the remaining conductors in the wiring layer. The electrical coil is therefore produced directly in the wiring layer and not applied as a prefabricated element.

The wiring layer can be formed with the at least one conductor loop in a manner directly adjoining the contact side of the at least one semiconductor chip. This affords the advantage that as a result of the integration of the coil into the wiring layer, a separate layer is not required for forming the coil. In this embodiment, the additional function of an electrical coil can be realized with minimal manufacturing outlay without the addition of a further layer to those required anyway. This is appropriate in the case of wiring geometries which have enough space for the at least one conductor loop in the wiring layer.

Additionally or alternatively, an intervening wiring layer can be formed in a manner directly adjoining the contact side of the at least one semiconductor chip. Afterward, the wiring layer with the at least one conductor loop can be formed on the intervening wiring layer. An intervening wiring layer can be understood to be a layer which is similar to the wiring layer with the at least one conductor loop, but has substantially no conductor loop for forming an electrical coil, but rather only has the required wiring lines. A contact-making plane and a coil plane thus exist. This affords the advantage that the elements of the circuit can be wired with a wiring geometry that is optimal for the circuit, and the lines required for the electrical coil can be realized independently of the wiring geometry of the circuit. The two wiring layers can be formed by means of the same semiconductor technology method.

In this case, an intermediate plane can be formed in a manner directly adjoining the contact side of the at least one semiconductor chip and the wiring layer can be formed with the at least one conductor loop on the intermediate plane, wherein a thickness of the intermediate plane is set depending on a predetermined distance between the at least one conductor loop and the contact side. The intermediate plane can be constructed from one or a plurality of layers and comprise a wiring layer.

The at least one conductor loop can extend in the wiring layer beyond a region covered by the at least one semiconductor chip. Consequently, the conductor loop can be led beyond outer limits of the contact side of the at least one semiconductor chip and thus extend into a region which is not covered by the semiconductor chip, but rather by the potting compound. Consequently, the conductor loop can span an area that is larger than the semiconductor chip. By way of example, the at least one conductor loop can extend in the wiring layer over at least two semiconductor chips. An effective antenna area can be enlarged as a result.

In accordance with one embodiment, the method can comprise a step of fitting the at least one semiconductor chip by the contact side to a carrier substrate, a step of encapsulating the at least one semiconductor chip on the carrier substrate with the potting compound, and a step of detaching the carrier substrate from the at least one semiconductor chip, wherein the contact side of the at least one semiconductor chip is uncovered. The semiconductor chip which is encapsulated with the potting compound apart from the contact side can be produced in this way. Fitting the at least one semiconductor chip by the contact side to a carrier substrate can be understood to mean, for example, adhesive bonding thereon by means of an adhesive, e.g. an adhesive film. In this case, the adhesive film may have been or be provided on the carrier substrate, and the at least one chip can be placed thereon. The carrier substrate can have the form of a wafer, for example. In the process of detaching the carrier substrate from the at least one semiconductor chip, carrier substrate and adhesive from that of the carrier substrate are removed from the at least one semiconductor chip. This affords the advantage that the method according to the disclosure can readily be incorporated into a conventional wafer level package process sequence.

The wiring layer with the at least one conductor loop can be formed by means of a semiconductor technology method. A semiconductor technology method can be understood to be, for example, metal sputtering, resist coating, lithography or electro deposition. This affords the advantage that the wiring layer with the at least one conductor loop can be formed using known manufacturing methods from semiconductor technology. Consequently, the wiring layer with the at least one conductor loop can be integrated into existing process sequences very well and expediently in terms of manufacturing outlay.

The steps of the method according to the disclosure can advantageously be performed in the context of a wafer level process.

The present disclosure furthermore provides an electrical circuit comprising at least one semiconductor chip, comprising the following feature:

a wiring layer at a contact side of the at least one semiconductor chip, which is encapsulated with a potting compound apart from the contact side, wherein the wiring layer has at least one conductor loop for the purpose of forming an electrical coil.

The coil can function as a device for emitting or receiving data. The coil can also be used for supplying the circuit with energy.

The present disclosure furthermore provides a sensor module comprising an electrical circuit according to the disclosure.

A sensor module can be understood to be, for example, a pressure sensor, inertial sensor, magnetic sensor or the like with an evaluation IC. The electrical circuit according to the disclosure can advantageously be used in the sensor module. Consequently, the wafer level package process according to the disclosure can be utilized for sensor modules. One possibility for using sensors resides in RFID tags, for example. In this context, e.g. a pressure sensor can be read via radio.

### BRIEF DESCRIPTION OF THE DRAWINGS

The disclosure is explained in greater detail by way of example below with reference to the accompanying drawings, in which:

FIGS. 1 to 4 show an illustration of an electrical circuit in the production process in accordance with exemplary embodiments of the present disclosure;

FIG. 5 shows a plan view of an electrical circuit in accordance with an exemplary embodiment of the present disclosure; and

FIG. 6 shows a flow chart of a method in accordance with an exemplary embodiment of the present disclosure.

### DETAILED DESCRIPTION

In the following description of preferred exemplary embodiments of the present disclosure, identical or similar reference symbols are used for the elements which are illustrated in the different figures and act similarly, a repeated description of these elements being dispensed with.

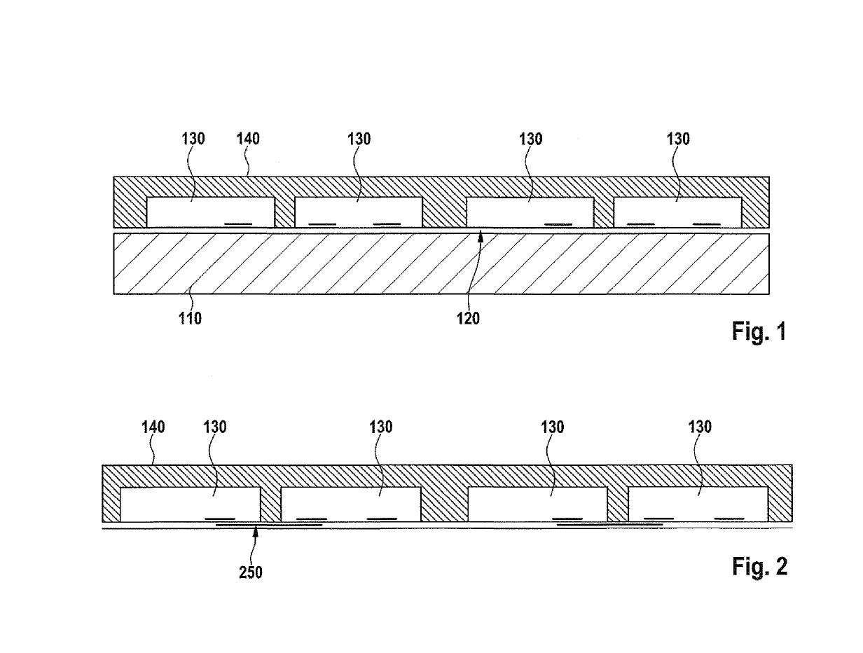

FIG. 1 shows a sectional view of a layer construction of an electrical circuit in the production process. In this case, the circuit is produced by means of a method in accordance with an exemplary embodiment of the present disclosure. The layer construction comprises a carrier substrate 110, an adhesive in the form of an adhesive film 120, semiconductor chips 130 and a molding or potting compound 140. The method is based on a wafer level package process. Fixing of the chips 130 by means of the adhesive film 120 on the carrier substrate 110 and subsequent overmolding or encapsulation are effected in this case.

A thin layer of the adhesive film 120 is situated at the top side of the carrier substrate 110. The semiconductor chips 130 are adhesively bonded adjacent to one another on a surface of the adhesive film 120. The semiconductor chips 130 can be arranged in one or a plurality of rows or some other pattern on the adhesive film 120. The adhesively bonded semiconductor chips 130 are encapsulated in the potting compound 140. Only a cross section through a layer construction of part of a wafer is illustrated in the sectional view in FIG. 1, for the sake of clarity and expediency. The structures shown can be repeated on the entire wafer in the manner shown.

The carrier substrate 110 consists of a material suitable for the process, for example a wafer. The carrier substrate can be produced here from a suitable material known in the field. Of course, a combination of suitable materials can also be involved in this case. The carrier substrate 110 has two main surfaces.

The adhesive film 120 is applied in a thin layer to one of the two main surfaces of the carrier substrate 110, the upper main surface in FIG. 1. The adhesive film 120 covers the entire main surface of the carrier substrate 110 shown in FIG. 1. The adhesive film 120 can be produced from a suitable adhesive material known in the field. Of course, a combination of suitable materials can also be involved in this case.

The semiconductor chips 130 are each fixed to the adhesive film 120 at one of their main surfaces. The semiconductor chips 130 are identical or different integrated circuits based on a semiconductor substrate, for example silicon. FIG. 1 shows four semiconductor chips 130 by way of example. The semiconductor chips 130 will hereinafter be designated as chip A, chip B, chip C and chip D from left to right in FIG. 1, for the purpose of better clarity. Chips A and B are assigned to a first electrical circuit, and chips C and D are assigned to a second electrical circuit. The lateral distance between chip A and chip B, and also between chip C and chip D, is smaller than the lateral distance between chip B and chip C, having approximately half the magnitude thereof in FIG. 1. Connection pads of the semiconductor chips 130 are situated at the lower side, by which the semiconductor chips 130 are adhesively bonded onto the adhesive film 120. In this case, the lower side of the semiconductor chips 130 is the active side or contact side of the semiconductor chips 130. The connection pads or electrical contacts of the semiconductor chips 130 are illustrated as flat rectangles at the lower ends of the chips in FIG. 1. In FIG. 1, chip A and chip C each have one connection pad, and chip B and chip D each have two connection pads. The semiconductor chips 130 can have further connection pads situated in front of or behind the sectional plane chosen in FIG. 1.

The molding or potting compound 140 (also known as mold compound) can be produced from a suitable material known in the field. Of course, a combination of suitable materials can also be involved in this case. In FIG. 1, the potting compound 140 is arranged on the semiconductor chips 130 as a covering layer that is planar toward the top. The potting compound 140 surrounds and covers the semiconductor chips 130 at all sides apart from that by which the semiconductor chips 130 are fixed to the adhesive film 120. The potting compound 140 forms a continuous layer around all the semiconductor chips 130 arranged on the adhesive film 120 and on said semiconductor chips. In regions of the adhesive film 120 at which no semiconductor chip 130 is adhesively bonded thereon, the potting compound 140 is in contact with the adhesive film 120. As is shown in FIG. 1, the active sides of the semiconductor chips 130 and the potting compound 140 terminate flush with the adhesive film 120 on one plane.

Consequently, the layer construction shown in FIG. 1 can be produced by means of the wafer level package process by virtue of the semiconductor chips 130 that are to be packaged being fixed with the active side downward by means of a suitable material, preferably an adhesive film 120, onto the carrier substrate 110. The semiconductor chips 130 are then overmolded or encapsulated with the potting compound 140 by means of a suitable molding method; by way of example, film molding is expedient.

FIG. 2 shows a sectional view of a layer construction of an electrical circuit in the production process. In this case, the circuit is produced by means of a method in accordance with an exemplary embodiment of the present disclosure. The layer construction illustrated in FIG. 2 is similar to that shown in FIG. 1, with the difference that the adhesive film 120 and the carrier substrate 110 have been removed and a first wiring layer 250 is arranged at the then exposed surface of the semiconductor chips 130 and the potting compound 140.

The first wiring plane or wiring layer 250 covers the active sides of the semiconductor chips 130 and the lower surface of the potting compound 140. Conductive connections for wiring the semiconductor chips among one another and externally (the latter are not illustrated in FIG. 2) are formed on a surface of the wiring layer 250 that faces the semiconductor chips 130. FIG. 2 illustrates two conductive connections or conductor tracks of chips for interconnecting the latter by means of flat rectangles in the first wiring layer 250. The connections shown in FIG. 2 run between the connection pad of chip A and a connection pad of chip B and between the connection pad of chip C and a connection pad of chip D. There is no conductive connection between chip B and chip C, since these chips are each assigned to different electrical circuits which are separated subsequently. In FIG. 2, the first wiring layer 250 has approximately the thickness of the adhesive film 120 from FIG. 1.

In order to arrive at the layer construction shown in FIG. 2 proceeding from the layer construction shown in FIG. 1, further steps of a wafer level package process are performed. Proceeding from the state in FIG. 1, the adhesive film 120 and the carrier substrate 110 are detached from the semiconductor chips 130 and the molding or potting compound 140. A type of chip-molding compound composite wafer is thus obtained. On account of the wafer form, this composite wafer can then be processed further in known installations appertaining to semiconductor technology. After the removal of the film 120 and the carrier substrate 110, the first wiring plane 250 is produced with the aid of semiconductor technologies, such as resist coating, metal sputtering, lithography, etc. By means of semiconductor technology methods such as, for example, metal sputtering, lithography or electrodeposition, the electrical wiring of the semiconductor chip 130, or of a plurality of chips in the case of different semiconductor chips in one package, is realized.

FIG. 3 shows a sectional view of a layer construction of an electrical circuit in the production process. In this case, the circuit is produced by means of a method in accordance with an exemplary embodiment of the present disclosure. The layer construction illustrated in FIG. 3 is similar to that shown in FIG. 2, with the difference that a second wiring layer 360 is applied on the first wiring layer 250.

In FIG. 3, the second wiring layer 360 has two conductor loops 370 for forming a respective electrical coil and two contact pads or contact connection pads 380 for external connections. In FIG. 3, the second wiring layer 360 has approximately the same thickness as the first wiring layer 250 from FIG. 2. In this case, the first wiring layer 250 is arranged between the semiconductor chips 130 or the potting compound 140 and the second wiring layer 360. The conductor loops 370 are arranged on a surface of the second wiring layer 360 that faces the first wiring layer 250. The contact connection pads 380 are arranged on a surface of the second wiring layer 360 that is remote from the first wiring layer 250.

A first of the conductor loops 370 extends over an interspace and over edge regions of the adjacent chips A and B. A second of the conductor loops 370 extends over an interspace and over edge regions of the adjacent chips C and D. The first of the conductor loops is electrically conductively connected to a conductor track of the first wiring layer 250 via a plated-through hole. A connection pad of chips B and D is electrically conductively connected to one of the contact connection pads 380 in each case via a plated-through hole through the wiring layers 250, 360.

In order to arrive at the layer construction shown in FIG. 3 proceeding from the layer construction shown in FIG. 2, in one step of the wafer level package process, the two coils 370 are realized by means of known semiconductor technologies. By means of semiconductor technology methods such as metal sputtering, lithography or electrodeposition, an electrical wiring of a silicon chip 130 or of a plurality of chips 130 in the case of different silicon chips 130 in one package, and also contact pads 380 for making contact with the package are realized. In accordance with this exemplary embodiment, moreover, one or a plurality of coils 370 are realized on or in the wiring plane 370 by means of the same processes.

FIG. 4 shows a sectional view of a layer construction of an electrical circuit in the production process. In this case, the circuit is produced by means of a method in accordance with an exemplary embodiment of the present disclosure. The layer construction illustrated in FIG. 4 is similar to that shown in FIG. 3, with the difference that the layer construction from FIG. 4 is subdivided vertically into separate pieces. One subdivision is illustrated between chip B and chip C in FIG. 4. A further subdivision, shown at the left-hand edge of FIG. 4, is intended to indicate that the entire composite wafer rather than just the excerpt illustrated is subdivided in this way.

In order to arrive at the layer construction shown in FIG. 4, proceeding from the layer construction shown in FIG. 3, at a point in time in the context of the production method according to the present disclosure, a further step of the wafer level package process is performed. In this case, the wafer composite is singulated by sawing in order to obtain individual packages. In accordance with this exemplary embodiment, a first package comprises the first circuit comprising chips A and B, and a second package comprises the second circuit comprising chips A and B.

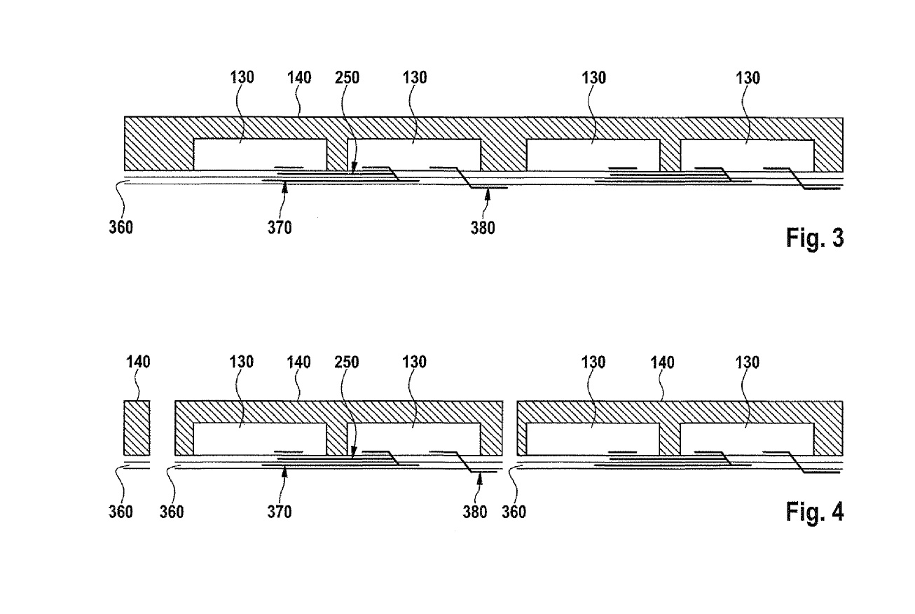

FIG. 5 shows a plan view of an electrical circuit in accordance with an exemplary embodiment of the present disclosure. The electrical circuit can be produced by means of a method for producing an electrical circuit as described with reference to FIGS. 1 to 4. The plan view reveals the semiconductor chips 130, the wiring between the chips, the potting compound 140, the conductor loop 370 for forming an electrical coil and the contact connection pads or contact pads 380.

The electrical circuit has a rectangular basic area. The electrical circuit has two semiconductor chips 130. The semiconductor chip 130 illustrated on the left in FIG. 5 has a larger basic area than the semiconductor chip 130 shown on the right. The semiconductor chips 130 are encapsulated in the potting compound 140, which surrounds said semiconductor chips. The wiring layers are not directly visible in FIG. 5, but rather only indirectly by virtue of the contact and conductor structures formed in them. The contact and conductor structures formed in the wiring layers comprise the wiring between the semiconductor chips 130, the conductor loop 370 and the contact connection pads 380.

The wiring between the semiconductor chips 130 is illustrated in the center in FIG. 5 by means of six short lines which run at the same distance from one another and which electrically connect the two semiconductor chips 130. The lines of the wiring span the distance between the semiconductor chips 130 and extend on both sides further to the extent of one quarter of their line length over the respective chip edge onto the semiconductor chips 130.

The conductor loop 370 has four rectangular-spiral windings. The lines of the wiring between the semiconductor chips 130 are arranged in the center of the windings of the conductor loop 370. The outermost winding, that is to say the winding having the largest winding diameter, runs partly alongside a basic area of the semiconductor chips 130 and moreover in edge regions of the semiconductor chips 130. One end of the conductor loop has an outer connection pad or a plated-through hole to a connection of one of the semiconductor chips 130. The conductor loop can occupy, for example, between one quarter and three quarters of a basic area of the electrical circuit.

In FIG. 5, the contact connection pads 380 are arranged in edge regions of the electrical circuit. Twelve contact connection pads 380 are illustrated as an example here. In the plan view shown, the contact connection pads 380 have a square basic area. Leads to the contact connection pads 380 are not illustrated in FIG. 5.

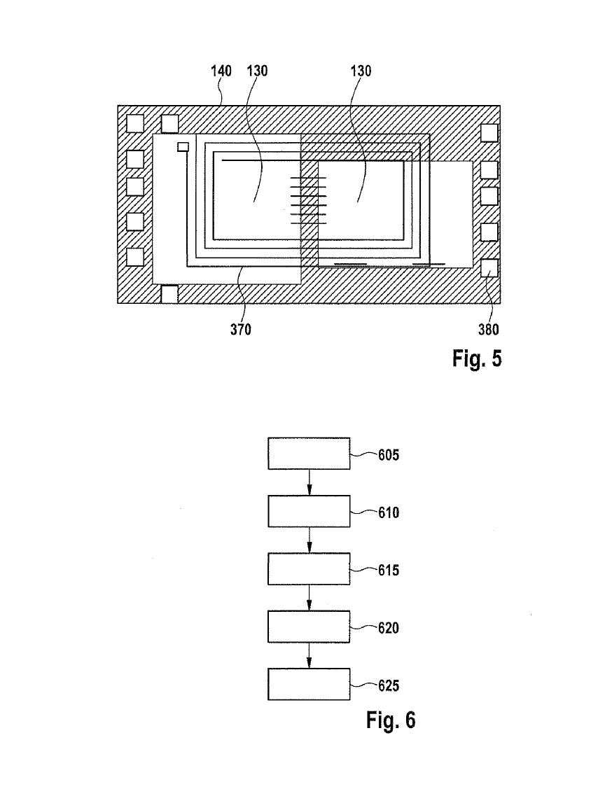

FIG. 6 shows a flowchart of a method for producing an electrical circuit comprising at least one semiconductor chip, in accordance with an exemplary embodiment of the present disclosure. In a step 605, at least one semiconductor chip is fitted by the contact side to a carrier substrate. In a step 610, the at least one semiconductor chip on the carrier substrate is encapsulated with the potting compound. In a step 615, the carrier substrate is detached from the at least one semiconductor chip, wherein the contact side of the at least one semiconductor chip is exposed. Consequently, at least one semiconductor chip which is encapsulated with a potting compound apart from the contact area is then provided. In a step 620, by means of a semiconductor technology method such as, for example, metal sputtering, resist coating, lithography or electrodeposition, a wiring layer is formed at a contact side of the at least one semiconductor chip, wherein the wiring layer has at least one conductor loop for the purpose of forming an electrical coil. In a step 625, the at least one encapsulated semiconductor chip provided with the wiring layer is singulated. A wafer level package with an integrated electrical coil is thus obtained.

The exemplary embodiments described and shown in the figures have been chosen merely by way of example. Different exemplary embodiments can be combined with one another completely or with regard to individual features. Moreover, one exemplary embodiment can be supplemented by features of a further exemplary embodiment. Depending on what preprocessing has already been effected or what postprocessing will also be effected, the method for producing an electrical circuit can also comprise only one or individual method steps from among the method steps described with reference to the figures.

What is claimed is:

1. A method for producing an electrical circuit having at least one semiconductor chip, comprising:
forming a wiring layer at a contact side of the at least one semiconductor chip, which is encapsulated with a potting compound apart from the contact side, wherein the wiring layer has at least one conductor loop configured to form an electrical coil.

2. The method according to claim 1, wherein the wiring layer is formed with the at least one conductor loop in a manner directly adjoining the contact side of the at least one semiconductor chip.

3. The method according to claim 1, wherein an intervening wiring layer is formed in a manner directly adjoining the contact side of the at least one semiconductor chip and the wiring layer with the at least one conductor loop is formed on the intervening wiring layer.

4. The method according to claim 2, wherein an intermediate plane is formed in a manner directly adjoining the contact side of the at least one semiconductor chip and the wiring layer is formed with the at least one conductor loop on the intermediate plane, wherein a thickness of the intermediate plane is set depending on a predetermined distance between the at least one conductor loop and the contact side.

5. The method according to claim 1, wherein the at least one conductor loop extends in the wiring layer beyond a region covered by the at least one semiconductor chip.

6. The method according to claim 1, further comprising:
fitting the at least one semiconductor chip by the contact side to a carrier substrate;
encapsulating the at least one semiconductor chip on the carrier substrate with the potting compound, and
detaching the carrier substrate from the at least one semiconductor chip,
wherein the contact side of the at least one semiconductor chip is uncovered so that the semiconductor chip which is encapsulated with the potting compound is set apart from the contact side.

7. The method according to claim 1, wherein the wiring layer with the at least one conductor loop is formed by a semiconductor technology method.

8. The method according to claim 1, wherein the method is performed in the context of a wafer level process.

9. An electrical circuit, comprising:
at least one semiconductor chip; and
a wiring layer positioned at a contact side of the at least one semiconductor chip, which is encapsulated with a potting compound apart from the contact side,
wherein the wiring layer has at least one conductor loop configured to form an electrical coil.

10. A sensor module comprising the electrical circuit of claim 9.
